(19) United States
(12) Patent Application Publication
(10) Pub. No.: US 2026/0060138 A1
(43) Pub. Date: Feb. 26, 2026

(54) DISPLAY DEVICE AND FABRICATION METHOD THEREOF

(71) Applicant: AUO Corporation, Hsinchu City (TW)

(72) Inventors: Wen-Wei Yang, Hsinchu City (TW); Kuan-Heng Lin, Hsinchu City (TW); Yi-Hong Chen, Hsinchu City (TW); Chia-An Lee, Hsinchu City (TW); Yu-Hsin Huang, Hsinchu City (TW); YinYu Chen, Hsinchu City (TW)

(73) Assignee: AUO Corporation, Hsinchu City (TW)

(21) Appl. No.: 18/935,666

(22) Filed: Nov. 4, 2024

(30) Foreign Application Priority Data
Aug. 23, 2024 (TW) 113131902

(51) Int. Cl. H01L 25/075; H01L 21/66; H01L 33/00; H01L 33/38; H01L 33/50; H01L 33/54; H01L 33/62

(52) U.S. Cl. CPC H01L 25/0753; H01L 22/34; H10H 20/01; H10H 20/831; H10H 20/8512; H10H 20/853; H10H 20/857

(57) ABSTRACT

A display device includes a circuit substrate, a first light-emitting diode (LED), a second LED, a repair LED, a first protective structure, and a second protective structure. The circuit substrate includes a first pixel region and a second pixel region. The first pixel region includes a first placement region and a first repair region, and the second pixel region includes a second placement region and a second repair region. The first LED and the second LED are respectively located on the first pixel region and the second pixel region. The repair LED is located on the first repair region. The first protective structure and the second protective structure are located on the first repair region and the second repair region respectively. The first protective structure is in contact with the repair LED.

### CROSS-REFERENCE TO RELATED APPLICATION

This application claims the priority benefit of Taiwan application serial no. 113131902, filed on Aug. 23, 2024. The entirety of the above-mentioned patent application is hereby incorporated by reference herein and made a part of this specification.

### BACKGROUND

### Technical Field

The disclosure relates to a display device and a fabrication method thereof.

### Description of Related Art

A light emitting diode (LED) is a light emitting element with characteristics such as low power consumption, high brightness, high resolution, and high color saturation, so it is suitable for constructing a pixel structure of an LED display panel.

The technology of transferring the LEDs to a circuit substrate is called mass transfer. However, the existing technology is prone to issues such as transposition errors, transfer failures, or LED failures when transferring the LEDs, causing some pixels in a display device to fail to operate normally, seriously affecting display quality. The LEDs with the transposition errors, transfer failures, or failures are typically removed, and the repair LEDs are transferred to the circuit substrate to replace the removed LEDs.

### SUMMARY

The disclosure provides a display device and a fabrication method thereof, which may reduce costs of a repair process.

At least one embodiment of the disclosure provides a display device, including a circuit substrate, a first light emitting diode, a second light emitting diode, a first insulation structure, a second insulation structure, a first top electrode, a second top electrode, a repair light emitting diode, a first protective structure, and a second protective structure. The circuit substrate includes a first bottom electrode located in a first pixel region and a second bottom electrode located in a second pixel region. The first pixel region includes a first placement region and a first repair region, and the second pixel region includes a second placement region and a second repair region. The first light emitting diode and the second light emitting diode are respectively located on the first pixel region and the second pixel region. The first insulation structure and the second insulation structure are respectively located on the first placement region and the second placement region, and are in contact with the first light emitting diode and the second light emitting diode respectively. The first top electrode and the second top electrode are respectively located on the first insulation structure and the second insulation structure. The second light emitting diode is sandwiched between the second bottom electrode and the second top electrode. The repair light emitting diode is located on the first repair region, and is electrically connected to the first bottom electrode. The first protective structure and the second protective structure are respectively located on the first repair region and the second repair region. The first protective structure is in contact with the repair light emitting diode.

At least one embodiment of the disclosure provides a fabrication method of a display device, including the following steps. A circuit substrate is provided, including a first bottom electrode located in a first pixel region and a second bottom electrode located in a second pixel region. The first pixel region includes a first placement region and a first repair region, and the second pixel region includes a second placement region and a second repair region. A first light emitting diode and a second light emitting diode are placed on the first pixel region and the second pixel region respectively. A first insulation structure and a second insulation structure are formed. The first insulation structure and the second insulation structure are respectively located on the first placement region and the second placement region, and are in contact with the first light emitting diode and the second light emitting diode respectively. A first top electrode and a second top electrode are formed. The first top electrode and the second top electrode are respectively located on the first insulation structure and the second insulation structure. The second light emitting diode is sandwiched between the second bottom electrode and the second top electrode. A test process is performed. The second light emitting diode emits light during the test process, and the first light emitting diode is faulty during the test process. A repair light emitting diode is provided on the first repair region. A first protective structure and a second protective structure are formed. The first protective structure and the second protective structure are respectively located on the first repair region and the second repair region. The first protective structure is in contact with the repair light emitting diode.

### BRIEF DESCRIPTION OF THE DRAWINGS

FIG. 1A is a schematic cross-sectional view of a display device according to an embodiment of the disclosure.

FIG. 1B is a schematic top view of a display device according to an embodiment of the disclosure.

FIGS. 2A to 2G are schematic cross-sectional views of various stages of a fabrication method of the display device in FIGS. 1A and 1B.

FIG. 3 is a schematic cross-sectional view of a display device according to an embodiment of the disclosure.

FIG. 4 is a schematic cross-sectional view of a display device according to an embodiment of the disclosure.

FIG. 5 is a schematic cross-sectional view of a display device according to an embodiment of the disclosure.

FIG. 6A is a schematic cross-sectional view of a display device according to an embodiment of the disclosure.

FIG. 6B is a schematic top view of a display device according to an embodiment of the disclosure.

FIGS. 7A to 7D are schematic cross-sectional views of various stages of a fabrication method of the display device in FIGS. 6A and 6B.

FIG. 8A is a schematic cross-sectional view of a display device according to an embodiment of the disclosure.

FIG. 8B is a schematic top view of a display device according to an embodiment of the disclosure.

FIGS. 9A to 9C are schematic cross-sectional views of various stages of a fabrication method of the display device in FIGS. 8A and 8B.

FIG. 10 is a schematic cross-sectional view of a display device according to an embodiment of the disclosure.

### DETAILED DESCRIPTION OF DISCLOSED EMBODIMENTS

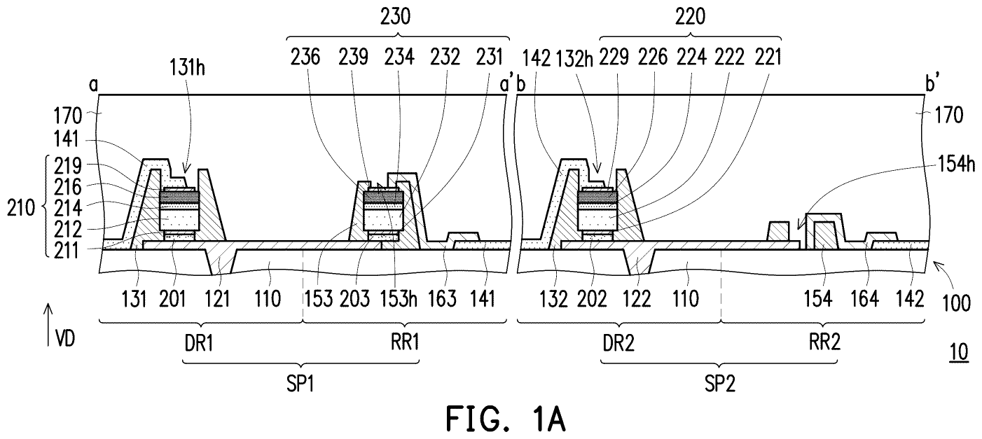

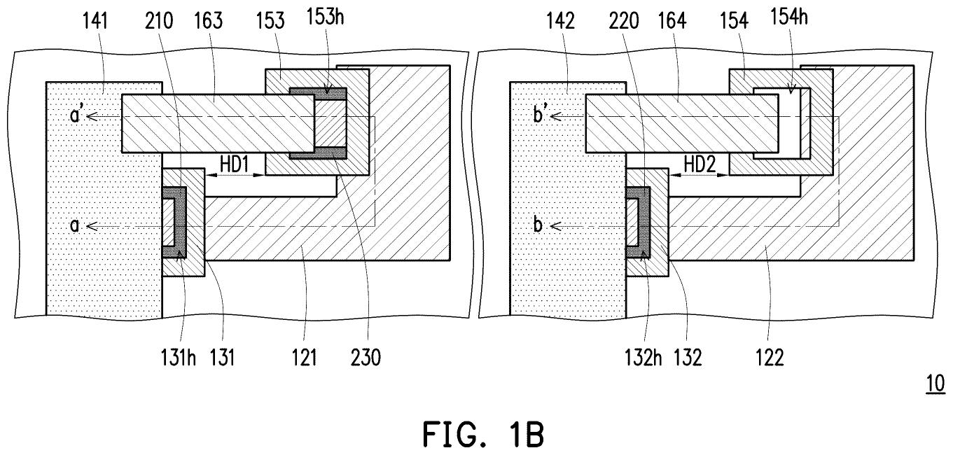

FIG. 1A is a schematic cross-sectional view of a display device 10 according to an embodiment of the disclosure. FIG. 1B is a schematic top view of the display device 10 according to an embodiment of the disclosure. FIG. 1A corresponds to positions of a line a-a′ and a line b-b′ in FIG. 1B. Referring to FIGS. 1A and 1B, the display device 10 includes a circuit substrate 100, a first light emitting diode 210, a second light emitting diode 220, a first insulation structure 131, a second insulation structure 132, a first top electrode 141, a second top electrode 142, a repair light emitting diode 230, a first protective structure 153, a second protective structure 154, a first connection structure 163, a second connection structure 164, and a covering structure 170.

The circuit substrate 100 has a first pixel region SP1 and a second pixel region SP2. The first pixel region SP1 includes a first placement region DR1 and a first repair region RR1 that are adjacent to each other, and the second pixel region SP2 includes a second placement region DR2 and a second repair area RR2 that are adjacent to each other.

The circuit substrate 100 includes an insulation layer 110, a first bottom electrode 121, and a second bottom electrode 122. For example, the circuit substrate 100 includes a substrate (e.g., glass, an organic material, or other suitable substrates) and multiple conductive layers and multiple insulation layers formed on the substrate. The uppermost insulation layer is the insulation layer 110 shown in FIG. 1A, and the uppermost conductive layer includes the first bottom electrode 121 and the second bottom electrode 122. The first bottom electrode 121 and the second bottom electrode 122 are located on the insulation layer 110 and are connected to other conductive structures located below the insulation layer 110 through a through hole in the insulation layer 110. In some embodiments, the circuit substrate 100 further includes multiple thin film transistors, and the first bottom electrode 121 and the second bottom electrode 122 are electrically connected to different thin film transistors respectively.

The first bottom electrode 121 and the second bottom electrode 122 are located in the first pixel region SP1 and the second pixel region SP2 respectively. In this embodiment, the first bottom electrode 121 extends from the first placement region DR1 to the first repair region RR1, and the second bottom electrode 122 extends from the second placement region DR2 to the second repair region RR2.

The first light emitting diode 210 and the second light emitting diode 220 are respectively located on the first pixel region SP1 and the second pixel region SP2. In some embodiments, both the first light emitting diode 210 and the second light emitting diode 220 are vertical light emitting diodes. The first light emitting diode 210 includes a first electrode 211, a first semiconductor layer 212, a light emitting layer 214, a second semiconductor layer 216, and a second electrode 219. The light emitting layer 214 is located between the first semiconductor layer 212 and the second semiconductor layer 216. The first electrode 211 and the second electrode 219 are in contact with the first semiconductor layer 212 and the second semiconductor layer 216 respectively. One of the first semiconductor layer 212 and the second semiconductor layer 216 is an N-type semiconductor, and the other is a P-type semiconductor. The second light emitting diode 220 includes a first electrode 221, a first semiconductor layer 222, a light emitting layer 224, a second semiconductor layer 226, and a second electrode 229. The light emitting layer 224 is located between the first semiconductor layer 222 and the second semiconductor layer 226. The first electrode 221 and the second electrode 229 are in contact with the first semiconductor layer 222 and the second semiconductor layer 226 respectively. One of the first semiconductor layer 222 and the second semiconductor layer 226 is an N-type semiconductor, and the other is a P-type semiconductor.

In some embodiments, the first electrode 211 of the first light emitting diode 210 is connected to the first bottom electrode 121 through a first conductive structure 201, and the first electrode 221 of the second light emitting diode 220 is connected to the second bottom electrode 122 through a second conductive structure 202. The first conductive structure 201 and the second conductive structure 202 include, for example, solder, a conductive adhesive, or other suitable conductive materials.

The first insulation structure 131 and the second insulation structure 132 are respectively located on the first placement region DR1 and the second placement region DR2, and are in contact with the first light emitting diode 210 and the second light emitting diode 220 respectively. In some embodiments, the first insulation structure 131 and the second insulation structure 132 surround the first light emitting diode 210 and the second light emitting diode 220 respectively. An opening 131h of the first insulation structure 131 overlaps the second electrode 219 of the first light emitting diode 210, and an opening 132h of the second insulation structure 132 overlaps the second electrode 229 of the second light emitting diode 220.

The first top electrode 141 and the second top electrode 142 are located on the first insulation structure 131 and the second insulation structure 132 respectively. In some embodiments, the first top electrode 141 is connected to the second electrode 219 of the first light emitting diode 210 through the opening 131h of the first insulation structure 131, and the second top electrode 142 is connected to the second electrode 229 of the second light emitting diode 220 through the opening 132h of the second insulation structure 132. The first top electrode 141 extends from the first insulation structure 131 above the first repair region RR1, and the second top electrode 142 extends from the second insulation structure 132 above the second repair region RR2. In some embodiments, the first top electrode 141 and the second top electrode 142 are electrically connected to each other, but the disclosure is not limited thereto.

In some embodiments, the first top electrode 141 and the second top electrode 142 respectively extend along a side wall of the first insulation structure 131 and a side wall of the second insulation structure 132 to a top surface of the insulation layer 110.

In this embodiment, the first light emitting diode 210 is sandwiched between the first bottom electrode 121 and the first top electrode 141, but the disclosure is not limited thereto. In other embodiments, the first light emitting diode 210 is shifted during a transposition process, resulting in the first bottom electrode 121 and/or the first top electrode 141 not in contact with the first light emitting diode 210. The second light emitting diode 220 is sandwiched between the second bottom electrode 202 and the second top electrode 142.

In this embodiment, the first light emitting diode 210 is faulty, so the repair light emitting diode 230 replace the first light emitting diode 210 to emit light. Reasons for the failure of the first light emitting diode 210 may include defects of the first light emitting diode 210 itself, damage to the first conductive structure 201, offset of the first light emitting diode 210 during the transposition process, etc.

The repair light emitting diode 230 is located on the first repair region RR1 and is electrically connected to the first bottom electrode 121. In some embodiments, the repair light emitting diode 230 is a vertical light emitting diode. The repair light emitting diode 230 includes a first electrode 231, a first semiconductor layer 232, a light emitting layer 234, a second semiconductor layer 236, and a second electrode 239. The light emitting layer 234 is located between the first semiconductor layer 232 and the second semiconductor layer 236. The first electrode 231 and the second electrode 239 are in contact with the first semiconductor layer 232 and the second semiconductor layer 236 respectively. One of the first semiconductor layer 232 and the second semiconductor layer 236 is an N-type semiconductor, and the other is a P-type semiconductor. In some embodiments, the first semiconductor layers 212, 222, and 232 are semiconductors of the same doping type, and the second semiconductor layers 216, 226, and 236 are semiconductors of the same doping type.

In some embodiments, the first electrode 231 of the repair light emitting diode 230 is connected to first bottom electrode 121 through a third conductive structure 203. The third conductive structure 203 includes, for example, solder, a conductive adhesive, or other suitable conductive materials.

In this embodiment, a portion of the repair light emitting diode 230 overlaps the first bottom electrode 121 in a vertical direction VD, and another portion of the repair light emitting diode 230 does not overlap the first bottom electrode 121 in the vertical direction VD. The vertical direction VD is, for example, a direction perpendicular to the top surface of the insulation layer 110.

The first protective structure 153 and the second protective structure 154 are located on the first repair region RR1 and the second repair region RR2 respectively. The first protective structure 153 and the second protective structure 154 are in contact with the first bottom electrode 121 and the second bottom electrode 122 respectively. The first protective structure 153 is in contact with the repair light emitting diode 230 and surrounds the repair light emitting diode 230 and the third conductive structure 203. A first through hole 153h of the first protective structure 153 overlaps the second electrode 239 of the repair light emitting diode 230. The second protective structure 154 has a second through hole 154h. In some embodiments, the first through hole 153h and the second through hole 154h partially overlap the first bottom electrode 121 and the second bottom electrode 122 respectively in the vertical direction VD.

In some embodiments, a horizontal distance HD1 between the first protective structure 153 and the first insulation structure 131 is substantially equal to a horizontal distance HD2 between the second protective structure 154 and the second insulation structure 132.

In some embodiments, the first protective structure 153 extends from a side wall of the repair light emitting diode 230 between a bottom surface of the repair light emitting diode 230 and the circuit substrate 100.

The first connection structure 163 and the second connection structure 164 are respectively filled in the first through hole 153h of the first protective structure 153 and the second through hole 154h of the second protective structure 154. The first connection structure 163 is connected to the second electrode 139 of the repair light emitting diode 230.

A contact area between the first connection structure 163 and the repair light emitting diode 230 does not overlap the first bottom electrode 121 in the vertical direction VD. Therefore, even if there is no repair light emitting diode 230, the first connection structure 163 will not be in contact with the first bottom electrode 121. The second connection structure 164 is separated from the second bottom electrode 122.

In some embodiments, the second connection structure 164 is in contact with the top surface of the insulation layer 110 through the second through hole 154h.

The covering structure 170 covers the first pixel region SP1 and the second pixel region SP2, and is in contact with the first insulation structure 131, the second insulation structure 132, the first top electrode 141, the second top electrode 142, the first protective structure 153, the second protective structure 154, the first connection structure 163, and the second connection structure 164. In some embodiments, the covering structure 170 is filled in the opening 131h of the first insulation structure 131, the opening 132h of the second insulation structure 132, the first through hole 153h of the first protective structure 153, and the second through hole 154h of the second protective structure 154. In some embodiments, the covering structure 170 includes a color conversion layer. In some embodiments, the covering structure 170 further includes encapsulant or other materials.

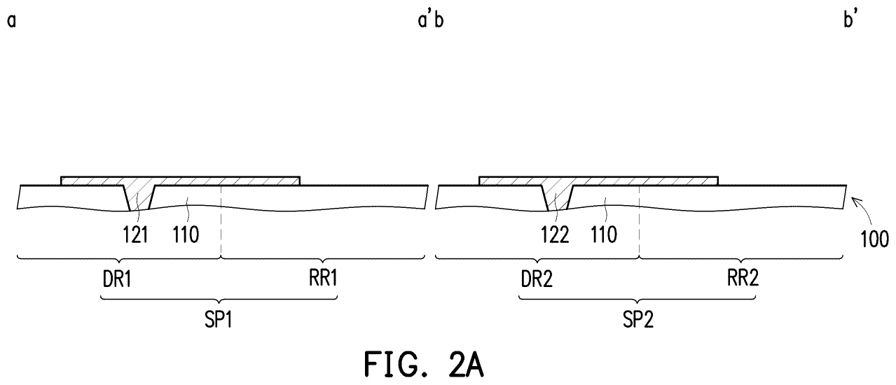

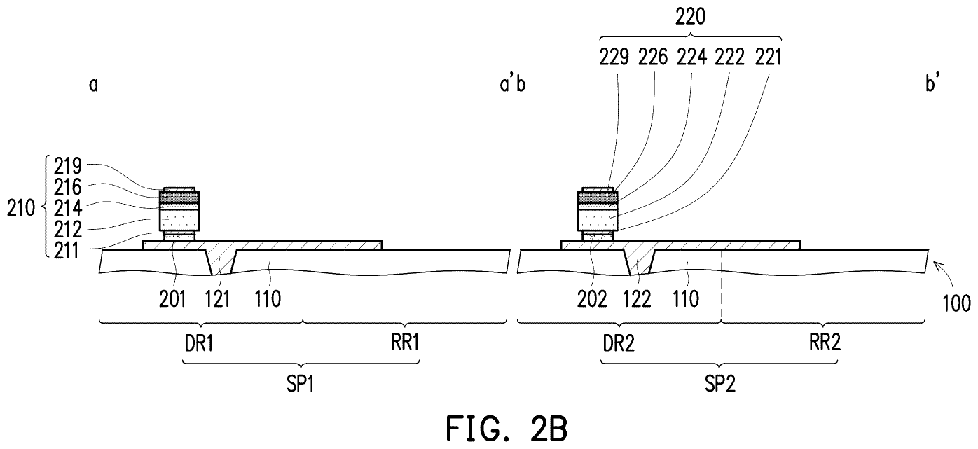

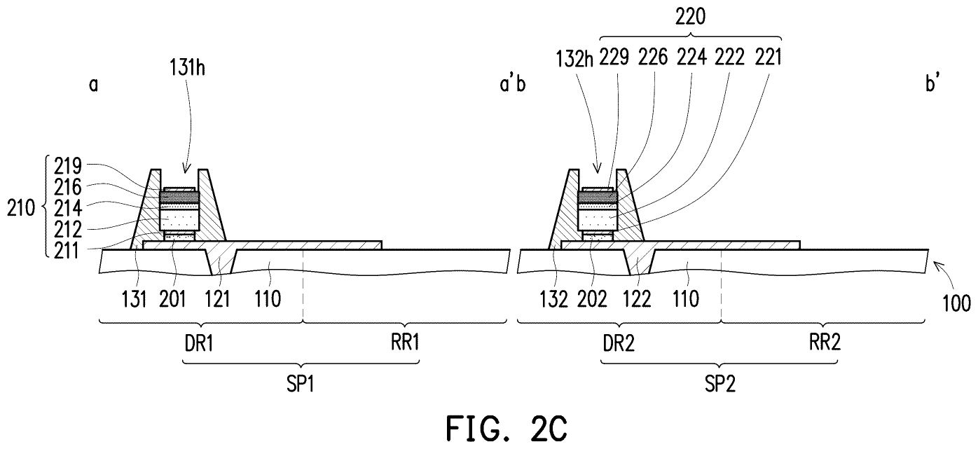

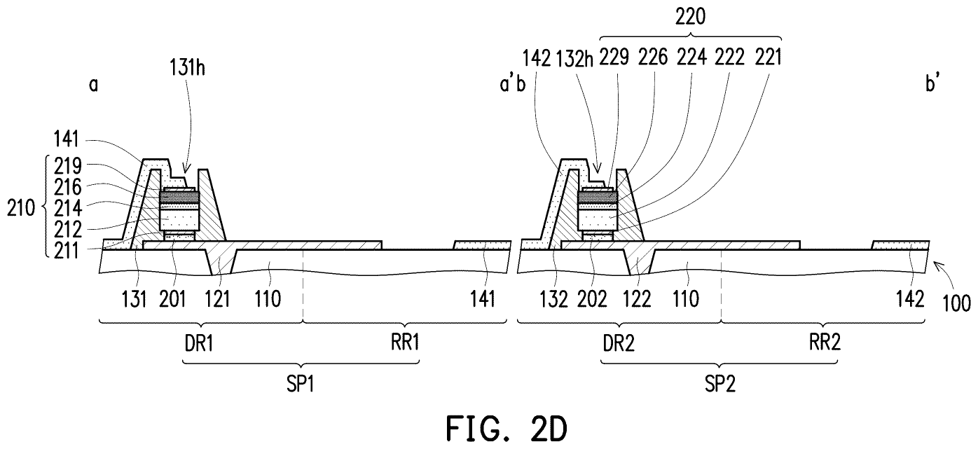

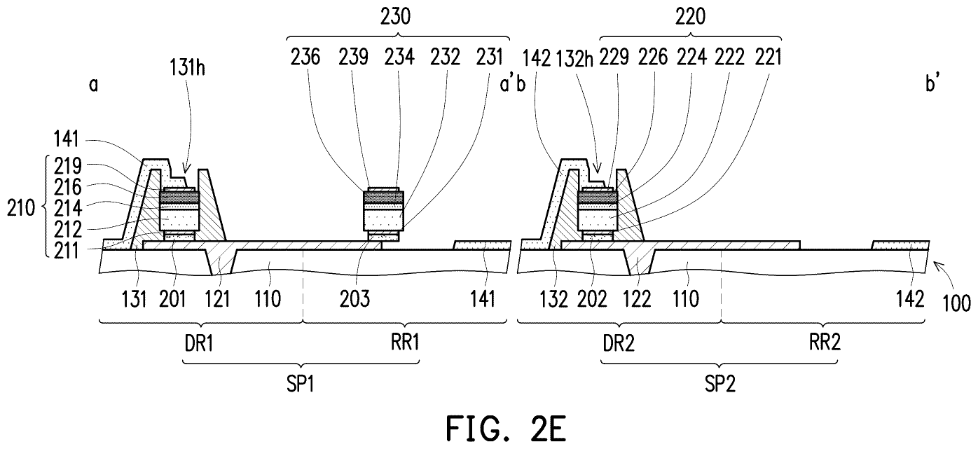

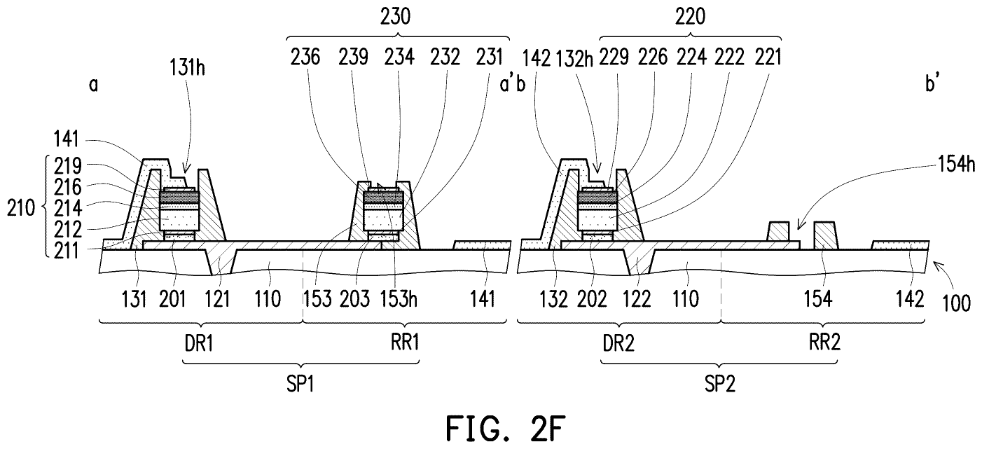

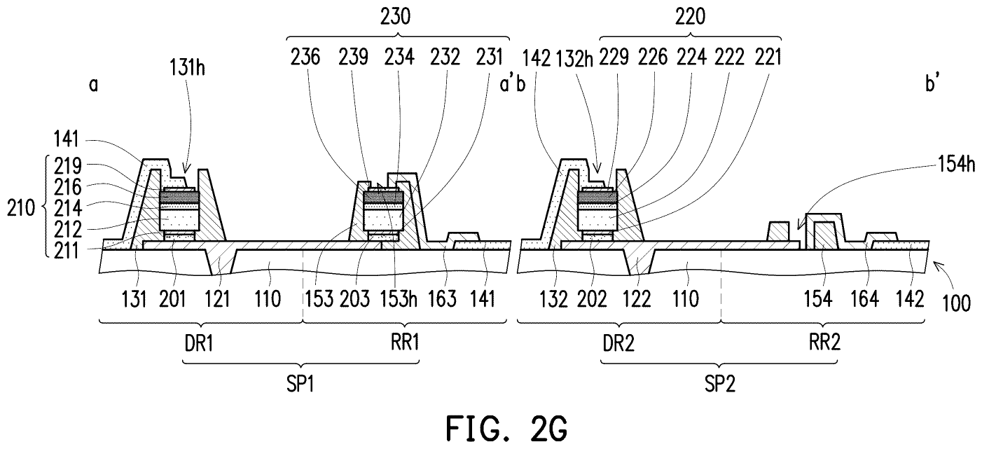

FIGS. 2A to 2G are schematic cross-sectional views of various stages of a fabrication method of the display device 10 in FIGS. 1A and 1B. Referring to FIG. 2A, the circuit substrate 100 is provided.

Referring to FIG. 2B, the first light emitting diode 210 and the second light emitting diode 220 are respectively placed on the first bottom electrode 121 of the first pixel region SP1 and the second bottom electrode 122 of the second pixel region SP2. In this embodiment, the first light emitting diode 210 and the second light emitting diode 220 are disposed on the circuit substrate 100 through a mass transfer process. The first light emitting diode 210 and the second light emitting diode 220 are respectively located on the first placement region DR1 and the second placement region DR2.

Referring to FIG. 2C, the first insulation structure 131 and the second insulation structure 132 are formed on the circuit substrate 100. For example, a photoresist material is first coated on the circuit substrate 100, and then the photoresist material is patterned through an exposure process and a development process to form the first insulation structure 131 and the second insulation structure 132. In other words, the first insulation structure 131 and the second insulation structure 132 include the cured photoresist material. In some embodiments, shapes of the first insulation structure 131 and the second insulation structure 132 are defined by the same photomask.

Referring to FIG. 2D, the first top electrode 141 and the second top electrode 142 are formed. The first top electrode 141 and the second top electrode 142 are respectively filled in the opening 131h of the first insulation structure 131 and the opening 132h of the second insulation structure 132.

Referring to FIG. 2E, a test process is performed to detect whether the first light emitting diode 210 and the second light emitting diode 220 may operate. In this embodiment, the second light emitting diode 220 emits the light during the test process, and the first light emitting diode 210 is faulty during the test process.

After the failure of the first light emitting diode 210 is confirmed, the repair light emitting diode 230 is provided on the first repair region RR1. The repair light emitting diode 230 is bonded to first bottom electrode 121.

Referring to FIG. 2F, the first protective structure 153 and the second protective structure 154 are formed on the circuit substrate 100. The first protective structure 153 and the second protective structure 154 are located on the first repair region RR1 and the second repair region RR2 respectively. For example, the photoresist material is first coated on the circuit substrate 100, and then the photoresist material is patterned through the exposure process and the development process to form the first protective structure 153 and the second protective structure 154. In other words, the first protective structure 153 and the second protective structure 154 include the cured photoresist material. In some embodiments, shapes of the first protective structure 153 and the second protective structure 154 are defined by the same photomask.

In this embodiment, both normally operating pixels and faulty pixels include a protective structure. Therefore, it is not necessary to modify the photomask used when forming the first protective structure 153 and the second protective structure 154 in response to a position of the repair light emitting diode 230. For example, in this embodiment, although the second light emitting diode 220 above the second pixel region SP2 is not faulty, the second protective structure 154 will still be formed above the second pixel region SP2. In other embodiments where the second light emitting diode 220 is faulty, the second protective structure 154 may be formed on the repair light emitting diode located on the second repair region RR2 without adjusting a mask design, and a structure similar to the first protective structure 153 and the repair light emitting diode 230 in FIG. 2F is obtained on the second pixel region SP. Based on the above, costs of redesigning the photomask may be saved, thereby reducing overall costs of a repair process.

Referring to FIG. 2G, the first connection structure 163 is formed in the first through hole 153h of the first protective structure 153. The second connection structure 164 is formed in the second through hole 154h of the second protective structure 154. For example, the conductive material is first formed entirely on the circuit substrate 100, and then the patterned photoresist layer is formed on the conductive material. Next, an etching process is performed using the patterned photoresist layer as a mask to pattern the conductive material, thereby forming the first connection structure 163 and the second connection structure 164. In other words, the first connection structure 163 and the second connection structure 164 may be formed at the same time.

In this embodiment, both the normally operating pixels and the faulty pixels include a connection structure. Therefore, it is not necessary to modify the photomask used to form the first connection structure 163 and the second connection structure 164 (the photomask used to form the patterned photoresist layer) in response to a position of the repair light emitting diode 230. For example, in this embodiment, although the second light emitting diode 220 above the second pixel region SP2 is not faulty, the second connection structure 164 will still be formed above the second pixel region SP2. In other embodiments where the second light emitting diode 220 is not faulty, the second connection structure 164 may be connected to the repair light emitting diode located on the second repair region RR2 through the second through hole 154h in the second protective structure 154 without adjusting the mask design, and a structure similar to the first connection structure 163 and the repair light emitting diode 230 in FIG. 2G is obtained on the second pixel region SP2. Based on the above, the costs of redesigning the photomask may be saved, thereby reducing the overall costs of the repair process.

In this embodiment, in order to avoid a short circuit between the connection structure and the bottom electrode, a portion of each of the connection structures (including the first connection structure 163 and the second connection structure 164) in the through hole (including the first through hole 153h and the second through hole 154h) does not overlap the corresponding bottom electrode in the vertical direction VD. Therefore, the contact area between the first connection structure 163 and the repair light emitting diode 230 does not overlap the first bottom electrode 121 in the vertical direction VD, while the second connection structure 164 is separated from the second bottom electrode 122. In other words, even if the first light emitting diode 210 is not faulty, and the repair light emitting diode 230 is not disposed above the first pixel region SP1, the first connection structure 163 will not be in contact with the first bottom electrode 121.

Finally, returning to FIGS. 1A and 1B, the covering structure 170 is formed on the first pixel region SP1 and the second pixel region SP2.

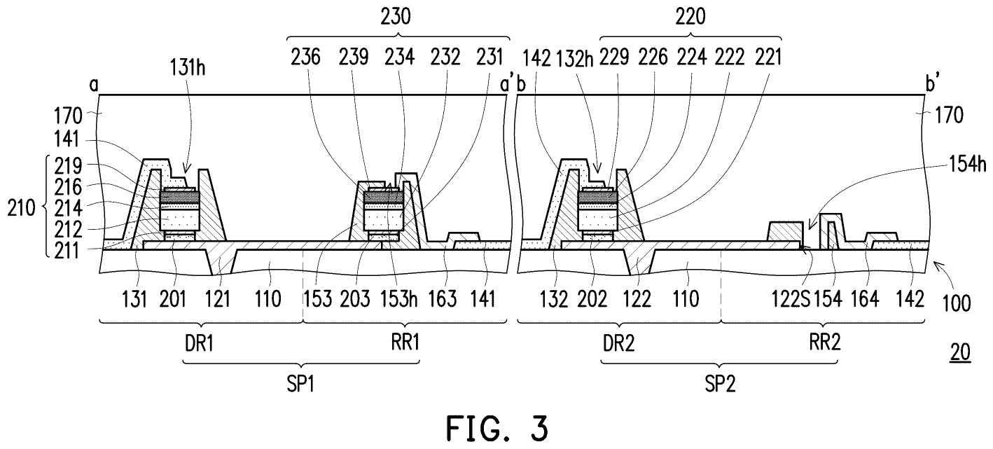

FIG. 3 is a schematic cross-sectional view of a display device 20 according to an embodiment of the disclosure. It is noted that some of the reference numerals and descriptions in FIGS. 1A and 1B will apply to FIG. 3. The same reference numerals will represent the same or similar components and the descriptions of the same technical contents will be omitted. Reference may be made to the above embodiment for the omitted descriptions, which will not be repeated in the following embodiments.

A difference between the display device 20 in FIG. 3 and the display device 10 in FIG. 1A includes that in the display device 20 o in FIG. 3, at least a portion of the side wall 122S of the second bottom electrode 122 close to the second connection structure 164 is covered by the second protective structure 154, thereby reducing a probability of a short circuit between the second bottom electrode 122 and the second connection structure 164.

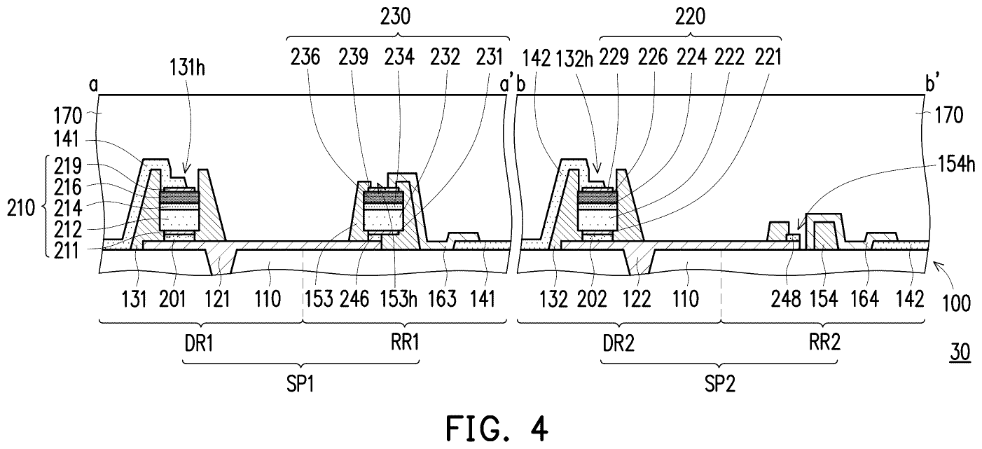

FIG. 4 is a schematic cross-sectional view of a display device 30 according to an embodiment of the disclosure. It is noted that some of the reference numerals and descriptions in FIGS. 1A and 1B will apply to FIG. 4. The same reference numerals will represent the same or similar components and the descriptions of the same technical contents will be omitted. Reference may be made to the above embodiment for the omitted descriptions, which will not be repeated in the following embodiments.

A difference between the display device 30 in FIG. 4 and the display device 10 in FIG. 1A includes that in the display device 10 in FIG. 1A, the third conductive structure 203 is first formed on the repair light emitting diode 230, and then the repair light emitting diode 230 is transposed to the circuit substrate 100, while in the display device 30 in FIG. 4, a third conductive structure 246 and a fourth conductive structure 248 are formed on the first bottom electrode 121 and the second bottom electrode 122 respectively, and then the repair light emitting diode 230 is transposed to the circuit substrate 100.

Referring to FIG. 4, the third conductive structure 246 and the fourth conductive structure 286 include, for example, solder, a conductive adhesive, or other suitable conductive materials. The first protective structure 153 and the second protective structure 154 are in contact with the third conductive structure 246 and the fourth conductive structure 248 respectively.

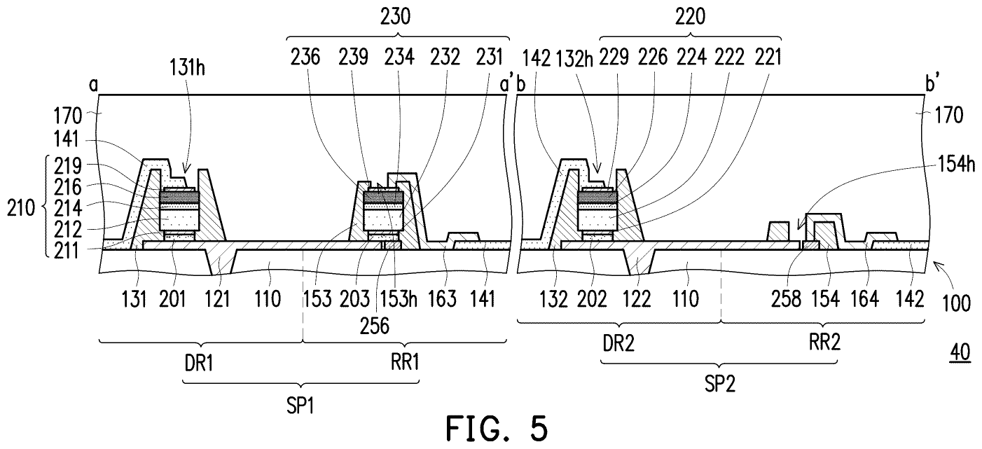

FIG. 5 is a schematic cross-sectional view of a display device 40 according to an embodiment of the disclosure. It is noted that some of the reference numerals and descriptions in FIGS. 1A and 1B will apply to FIG. 5. The same reference numerals will represent the same or similar components and the descriptions of the same technical contents will be omitted. Reference may be made to the above embodiment for the omitted descriptions, which will not be repeated in the following embodiments.

A difference between the display device 40 in FIG. 5 and the display device 10 in FIG. 1A includes that the display device 40 further includes a first support structure 256 and a second support structure 258. The first support structure 256 and the second support structure 258 are located on the first repair region RR1 and the second repair region RR2 respectively. The first support structure 256 is located between the repair light emitting diode 230 and the circuit substrate 100, and is used to support the repair light emitting diode 230. The first protective structure 153 and the second protective structure 154 are in contact with the first support structure 256 and the second support structure 258 respectively. In some embodiments, the second connection structure 164 is in contact with the second support structure 258 through the second through hole 154h.

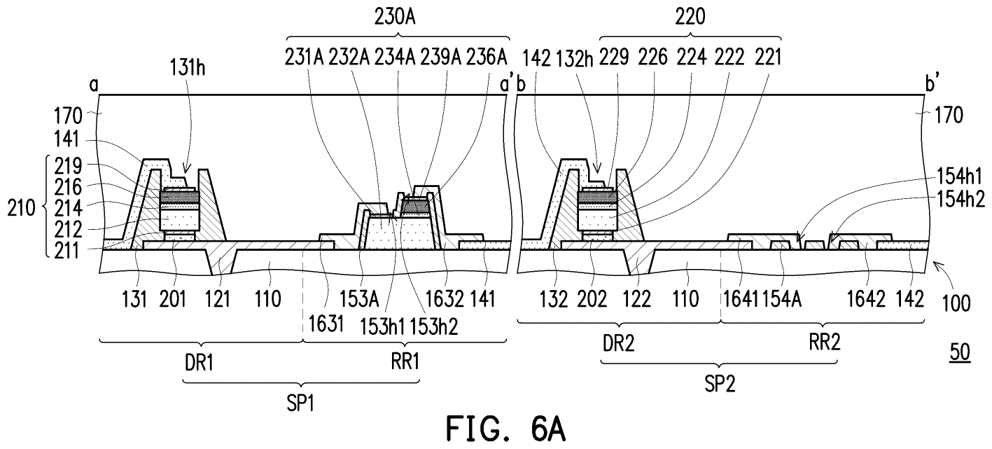

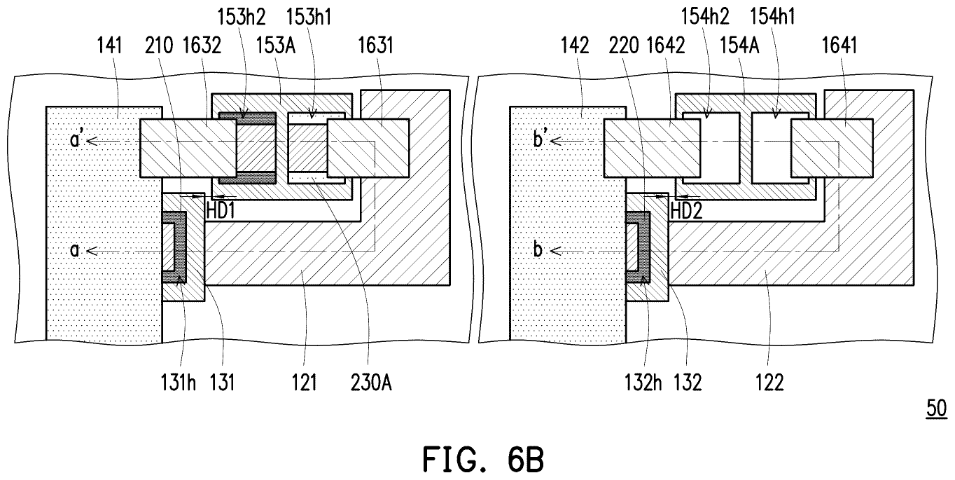

FIG. 6A is a schematic cross-sectional view of a display device 50 according to an embodiment of the disclosure. FIG. 6B is a schematic top view of the display device 50 according to an embodiment of the disclosure. FIG. 6A corresponds to the positions of the line a-a′ and the line b-b′ in FIG. 6B. It is noted that some of the reference numerals and descriptions in FIGS. 1A and 1B will apply to FIGS. 6A and 6B. The same reference numerals will represent the same or similar components and the descriptions of the same technical contents will be omitted. Reference may be made to the above embodiment for the omitted descriptions, which will not be repeated in the following embodiments.

A difference between the display device 50 in FIG. 6A and the display device 10 in FIG. 1A include that in the display device 50, a repair light emitting diode 230A is a horizontal light emitting diode.

Referring to FIGS. 6A and 6B, the repair light emitting diode 230A includes a first electrode 231A, a first semiconductor layer 232A, a light emitting layer 234A, a second semiconductor layer 236A, and a second electrode 239A. The light emitting layer 234A is located between the first semiconductor layer 232A and the second semiconductor layer 236A. The first electrode 231A and the second electrode 239A are in contact with the first semiconductor layer 232A and the second semiconductor layer 236A respectively. One of the first semiconductor layer 232A and the second semiconductor layer 236A is an N-type semiconductor, and the other is a P-type semiconductor. In some embodiments, the first semiconductor layers 212, 222, and 232A are semiconductors of the same doping type, and the second semiconductor layers 216, 226, and 236A are semiconductors of the same doping type.

The repair light emitting diode 230A is disposed on the first repair region RR1. In some embodiments, the repair light emitting diode 230A is bonded to the insulation layer 110 through an adhesive layer (not shown).

A first protective structure 153A and a second protective structure 154A are respectively located on the first repair region RR1 and the second repair region RR2. The first protective structure 153A is in contact with the repair light emitting diode 230A and surrounds the repair light emitting diode 230A. A first through hole 153h1 and a second through hole 153h2 of the first protective structure 153A overlap the first electrode 231A and the second electrode 239A of the repair light emitting diode 230A respectively.

The second protective structure 154A has a third through hole 154h1 and a fourth through hole 154h2.

In some embodiments, the horizontal distance HD1 between the first protective structure 153A and the first insulation structure 131 is substantially equal to the horizontal distance HD2 between the second protective structure 154A and the second insulation structure 132.

A first connection structure 1631 and a second connection structure 1632 are respectively filled in the first through hole 153h1 and the second through hole 153h2 of the first protective structure 153A. The first connection structure 1631 connects the first electrode 231A of the repair light emitting diode 230A to the first bottom electrode 121. The first connection structure 1631 extends from the first electrode 231A to the first bottom electrode 121 along the first protective structure 153A. The second connection structure 1632 connects the second electrode 239A of the repair light emitting diode 230A to the first top electrode 141. The second connection structure 1632 extends from the second electrode 239A to the first top electrode 141 along the first protective structure 153A.

A third connection structure 1641 and a fourth connection structure 1642 are respectively filled in the third through hole 154h1 and the fourth through hole 154h2 of the second protective structure 154A. The third connection structure 1641 is connected to the second bottom electrode 122, and the fourth connection structure 1642 is connected to the second top electrode 142. The third connection structure 1641 is separated from the fourth connection structure 1642. In some embodiments, the third connection structure 1641 and the fourth connection structure 1642 are in contact with the top surface of the insulation layer 110 through the third through hole 154h1 and the fourth through hole 154h2 respectively.

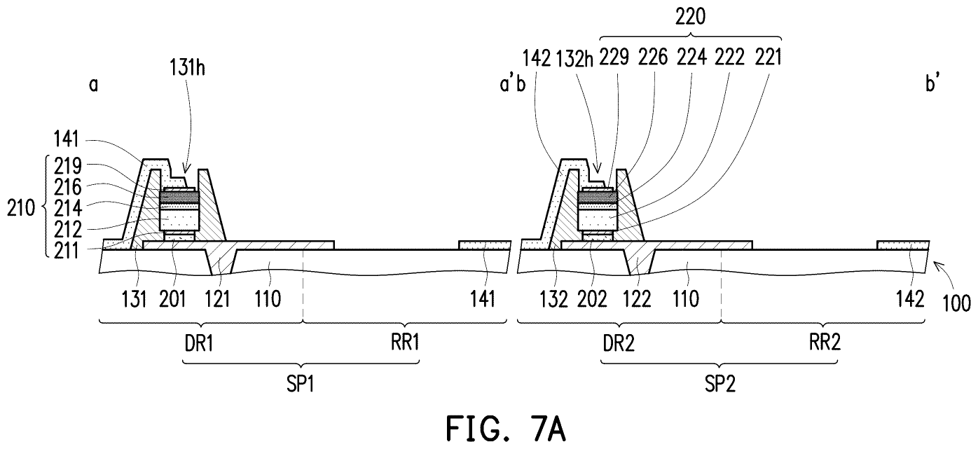

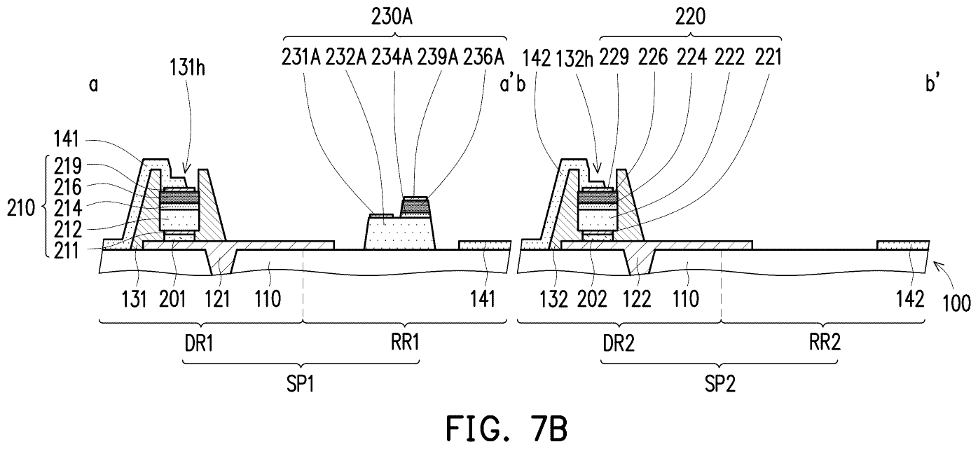

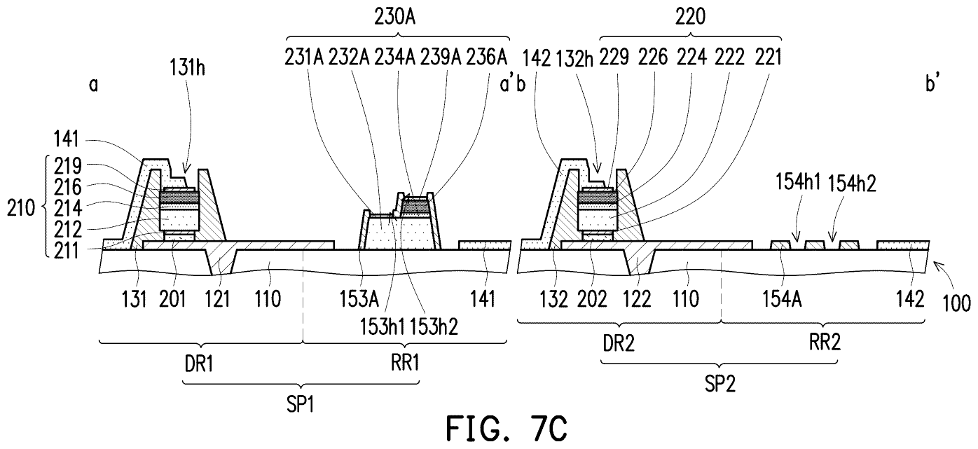

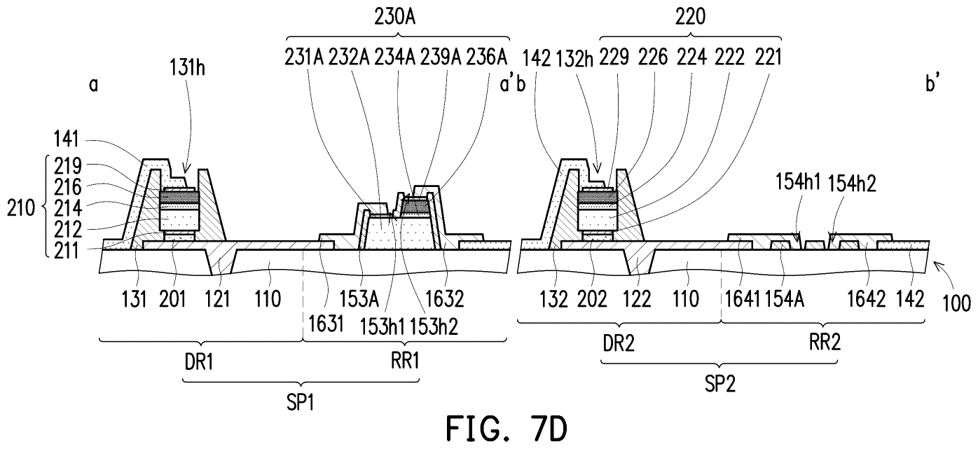

FIGS. 7A to 7D are schematic cross-sectional views of various stages of a fabrication method of the display device 50 in FIGS. 6A and 6B. Referring to FIG. 7A, the first light emitting diode 210 and the second light emitting diode 220 are bonded to the circuit substrate 100. The first insulation structure 131 and the second insulation structure 132 are formed on the first light emitting diode 210 and the second light emitting diode 220 respectively. The first top electrode 141 and the second top electrode 142 are formed on the first insulation structure 131 and the second insulation structure 132 respectively. For a method of forming the first insulation structure 131, the second insulation structure 132, the first top electrode 141, and the second top electrode 142, reference may be made to FIGS. 2A to 2D and related descriptions.

Referring to FIG. 7B, the test process is performed to detect whether the first light emitting diode 210 and the second light emitting diode 220 may operate. In this embodiment, the second light emitting diode 220 emits light during the test process, and the first light emitting diode 210 is faulty during the test process.

After the failure of the first light emitting diode 210 is confirmed, the repair light emitting diode 230A is provided on the first repair region RR1. The repair light emitting diode 230A is bonded to the insulation layer 110 through the adhesive layer (not shown), for example.

Referring to FIG. 7C, the first protective structure 153A and the second protective structure 154A are formed on the circuit substrate 100. The first protective structure 153A and the second protective structure 154A are located on the first repair region RR1 and the second repair region RR2 respectively. For example, the photoresist material is first coated on the circuit substrate 100, and then the photoresist material is patterned through the exposure process and the development process to form the first protective structure 153A and the second protective structure 154A. In other words, the first protective structure 153A and the second protective structure 154A include the cured photoresist material. In some embodiments, shapes of the first protective structure 153A and the second protective structure 154A are defined by the same photomask.

In this embodiment, both the normally operating pixels and the faulty pixels include a protective structure. Therefore, it is not necessary to modify the photomask used when forming the first protective structure 153A and the second protective structure 154A in response to a position of the repair light emitting diode 230A. For example, in this embodiment, although the second light emitting diode 220 above the second pixel region SP2 is not faulty, the second protective structure 154A will still be formed above the second pixel region SP2. In other embodiments where the second light emitting diode 220 is faulty, the second protective structure 154A may be formed on the repair light emitting diode located on the second repair region RR2 without adjusting the mask design, and a structure similar to the first protective structure 153A and the repair light emitting diode 230A in FIG. 7C is obtained. Based on the above, the costs of redesigning the photomask may be saved, thereby reducing the overall costs of the repair process.

Referring to FIG. 7D, the first connection structure 1631 and the second connection structure 1632 are respectively formed in the first through hole 153h1 and the second through hole 153h2 of the first protective structure 153A. The third connection structure 1641 and the fourth connection structure 1642 are respectively formed in the third through hole 154h1 and the fourth through hole 154h2 of the second protective structure 154A. For example, the conductive material is first formed entirely on the circuit substrate 100, and then the patterned photoresist layer is formed on the conductive material. Next, the etching process is performed using the patterned photoresist layer as the mask to pattern the conductive material, thereby forming the first connection structure 1631, the second connection structure 1632, the third connection structure 1641, and the fourth connection structure 1642. In other words, the first connection structure 1631, the second connection structure 1632, the third connection structure 1641, and the fourth connection structure 1642 may be formed at the same time.

In this embodiment, both the normally operating pixels and the faulty pixels include a connection structure. Therefore, it is not necessary to modify the photomask used when forming the first connection structure 1631, the second connection structure 1632, the third connection structure 1641, and the fourth connection structure 1642 (the photomask used to form the patterned photoresist layer) in response to the position of the repair light emitting diode 230A. For example, in this embodiment, although the second light emitting diode 220 above the second pixel region SP2 is not faulty, the third connection structure 1641 and the fourth connection structure 1642 will still be formed above the second pixel region SP2. In other embodiments where the second light emitting diode 220 is faulty, the third connection structure 1641 and the fourth connection structure 1642 may be connected to the repaired light emitting diode located on the second repair region RR2 through the third through hole 154h1 and the fourth through hole 154h2 in the second protective structure 154A without adjusting the mask design, and a structure similar to the first connection structure 1631, the second connection structure 1632, and the repair light emitting diode 230A in FIG. 7D is obtained. Based on the above, the costs of redesigning the photomask may be saved, thereby reducing the overall costs of the repair process.

Finally, returning to FIGS. 6A and 6B, the covering structure 170 is formed on the first pixel region SP1 and the second pixel region SP2.

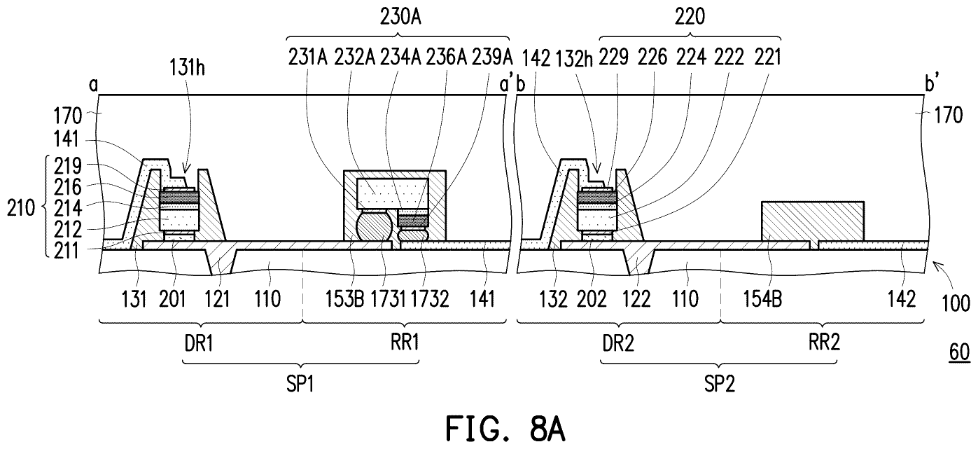

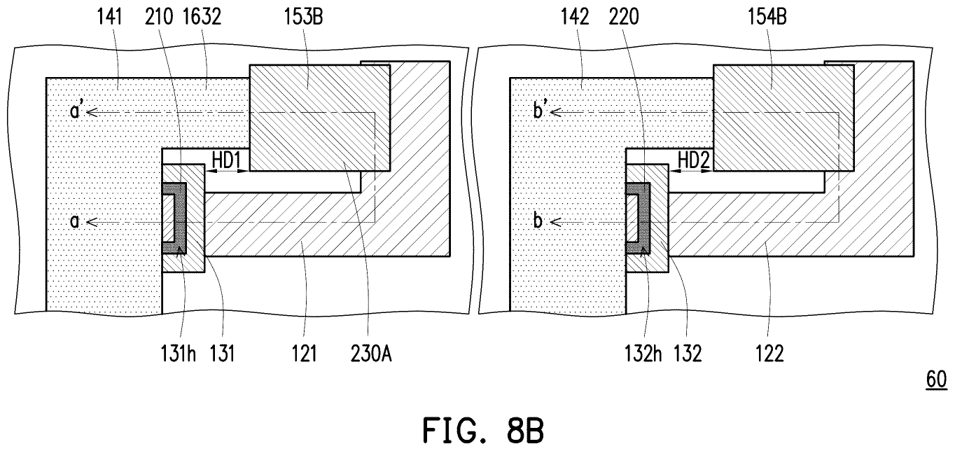

FIG. 8A is a schematic cross-sectional view of a display device 60 according to an embodiment of the disclosure. FIG. 8B is a schematic top view of the display device 60 according to an embodiment of the disclosure. FIG. 8A corresponds to the positions of the line a-a′ and the line b-b′ in FIG. 8B. It is noted that some of the reference numerals and descriptions in FIGS. 6A and 6B will apply to FIGS. 8A and 8B. The same reference numerals will represent the same or similar components and the descriptions of the same technical contents will be omitted. Reference may be made to the above embodiment for the omitted descriptions, which will not be repeated in the following embodiments.

A difference between the display device 60 in FIG. 8A and the display device 50 in FIG. 6A include that in the display device 60, the repair light emitting diode 230A is bonded to the circuit substrate 100 using a flip chip method.

Referring to FIGS. 8A and 8B, the repair light emitting diode 230A is disposed on the first repair region RR1.

A first connection structure 1731 and a second connection structure 1732 are located on the first bottom electrode 121 and the first top electrode 141 respectively. The first connection structure 1731 connects the first electrode 231A of the repair light emitting diode 230A to the first bottom electrode 121, and the second connection structure 1732 connects the second electrode 239A of the repair light emitting diode 230A to the first top electrode 141. In some embodiments, the first connection structure 1731 and the second connection structure 1732 are solder, a conductive adhesive, or other suitable materials. In this embodiment, the first connection structure 1731 and the second connection structure 1732 are separated from each other, but the disclosure is not limited thereto. In other embodiments, the first connection structure 1731 and the second connection structure 1732 include an anisotropic conductive adhesive, and the first connection structure 1731 and the second connection structure 1732 are connected to each other. In some embodiments, the first connection structure 1731 and the second connection structure 1732 are first formed on the repair light emitting diode 230A, and then the repair light emitting diode 230A is bonded to the circuit substrate 100. However, the disclosure is not limited thereto. In other embodiments, the first connection structure 1731 and the second connection structure 1732 are first formed on the circuit substrate 100, and then the repair light emitting diode 230A is bonded to the circuit substrate 100.

A first protective structure 153B and a second protective structure 154B are located on the first repair region RR1 and the second repair region RR2 respectively. The first protective structure 153B is in contact with the repair light emitting diode 230A, the first bottom electrode 121, and the first top electrode 141, and covers the repair light emitting diode 230A, the first connection structure 1731 and the second connection structure 1732. The first protective structure 153B helps to fix the repair light emitting diode 230A, and may be used to protect the first connection structure 1731 and the second connection structure 1732.

The second protective structure 154B is in contact with the second bottom electrode 122 and the second top electrode 142.

In some embodiments, the horizontal distance HD1 between the first protective structure 153B and the first insulation structure 131 is substantially equal to the horizontal distance HD2 between the second protective structure 154B and the second insulation structure 132.

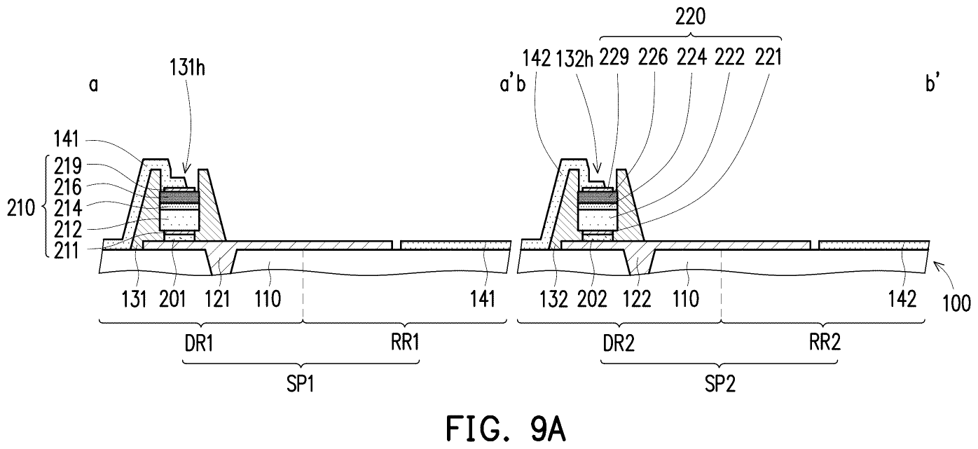

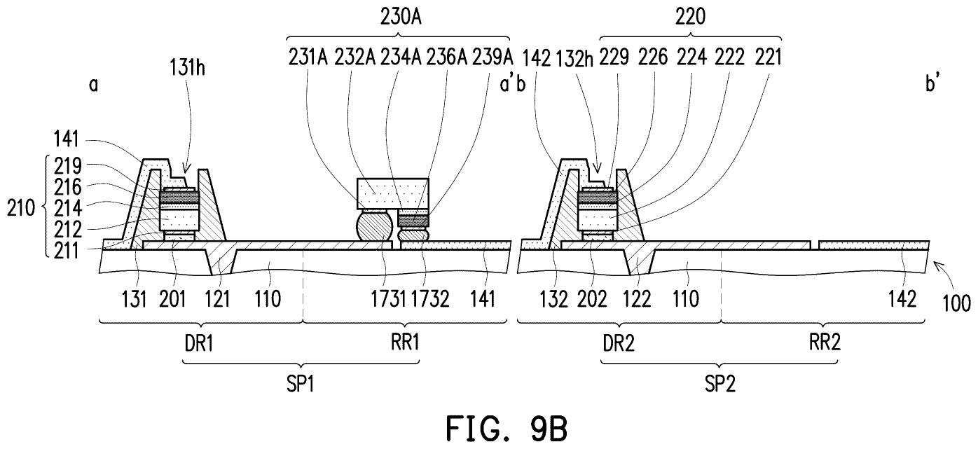

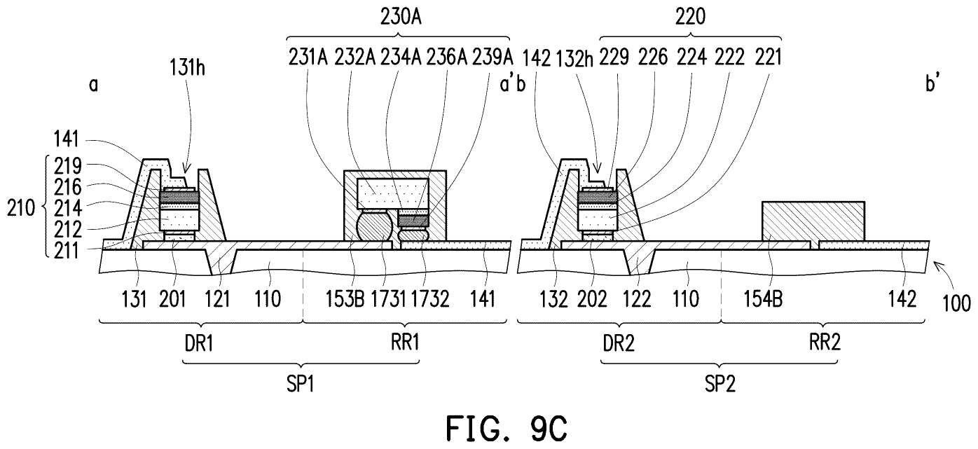

FIGS. 9A to 9C are schematic cross-sectional views of various stages of a fabrication method of the display device 60 in FIGS. 8A and 8B. Referring to FIG. 9A, the first light emitting diode 210 and the second light emitting diode 220 are bonded to the circuit substrate 100. The first insulation structure 131 and the second insulation structure 132 are formed on the first light emitting diode 210 and the second light emitting diode 220 respectively. The first top electrode 141 and the second top electrode 142 are formed on the first insulation structure 131 and the second insulation structure 132 respectively. For the method of forming the first insulation structure 131, the second insulation structure 132, the first top electrode 141, and the second top electrode 142, reference may be made to FIGS. 2A to 2D and related descriptions.

Referring to FIG. 9B, the test process is performed to detect whether the first light emitting diode 210 and the second light emitting diode 220 may operate. In this embodiment, the second light emitting diode 220 emits light during the test process, and the first light emitting diode 210 is faulty during the test process.

After the failure of the first light emitting diode 210 is confirmed, the repair light emitting diode 230A is provided on the first repair region RR1. The repair light emitting diode 230A is connected to the first bottom electrode 121 and the first top electrode 141 through the first connection structure 1731 and the second connection structure 1732.

Referring to FIG. 9C, the first protective structure 153B and the second protective structure 154B are formed on the circuit substrate 100. The first protective structure 153B and the second protective structure 154B are located on the first repair region RR1 and the second repair region RR2 respectively. For example, the photoresist material is first coated on the circuit substrate 100, and then the photoresist material is patterned through the exposure process and the development process to form the first protective structure 153B and the second protective structure 154B. In other words, the first protective structure 153B and the second protective structure 154B include the cured photoresist material. In some embodiments, shapes of the first protective structure 153B and the second protective structure 154B are defined by the same photomask.

In this embodiment, both the normally operating pixels and the faulty pixels include a protective structure. Therefore, it is not necessary to modify the photomask used when forming the first protective structure 153B and the second protective structure 154B in response to the position of the repair light emitting diode 230. For example, in this embodiment, although the second light emitting diode 220 above the second pixel region SP2 is not faulty, the second protective structure 154B will still be formed above the second pixel region SP2. In other embodiments where the second light emitting diode 220 is faulty, the second protective structure 154B may be formed on the repair light emitting diode located on the second repair region RR2 without adjusting the mask design, and a structure similar to the first protective structure 153B and the repair light emitting diode 230A in FIG. 9C is obtained. Based on the above, the costs of redesigning the photomask may be saved, thereby reducing the overall costs of the repair process.

Finally, returning to FIGS. 8A and 8B, the covering structure 170 is formed on the first pixel region SP1 and the second pixel region SP2.

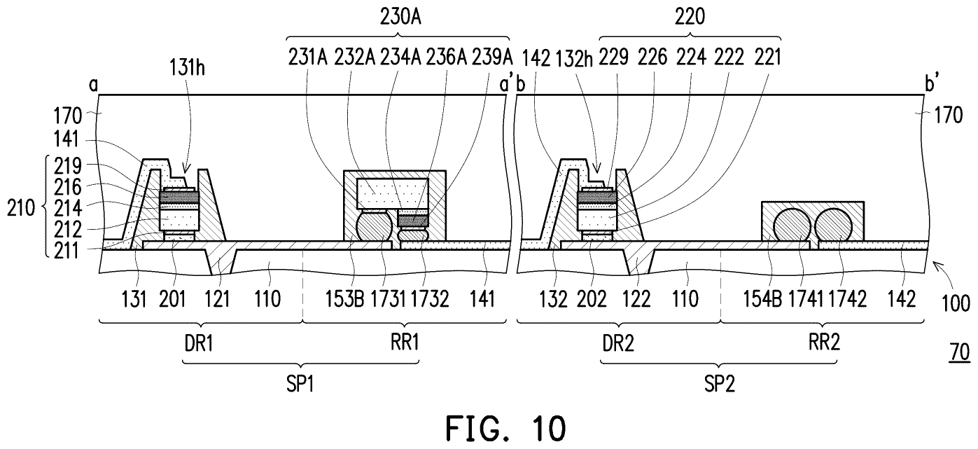

FIG. 10 is a schematic cross-sectional view of a display device 70 according to an embodiment of the disclosure. It is noted that some of the reference numerals and descriptions in FIGS. 8A and 8B will apply to FIG. 10. The same reference numerals will represent the same or similar components and the descriptions of the same technical contents will be omitted. Reference may be made to the above embodiment for the omitted descriptions, which will not be repeated in the following embodiments.

A difference between the display device 70 in FIG. 10 and the display device 60 in FIG. 8A includes that in the display device 70, a third connection structure 1741 and a fourth connection structure 1742 are formed on the second repair region RR2.

Referring to FIG. 10, the third connection structure 1741 and the fourth connection structure 1742 are located on the second bottom electrode 122 and the second top electrode 142 respectively. For example, the first connection structure 1731, the second connection structure 1732, the third connection structure 1741, and the fourth connection structure 1742 are formed on the circuit substrate 100 using the same process. In this embodiment, the connection structures are formed on the repair regions of all the pixels. Therefore, no matter which light emitting diode of the pixel is faulty subsequently, there will be a connection structure for connecting the repair light emitting diode in the corresponding repair region, thereby saving costs of adjusting a process of forming the connection structure.

In this embodiment, the third connection structure 1741 and the fourth connection structure 1742 are separated from each other, but the disclosure is not limited thereto. In other embodiments, the third connection structure 1741 and the fourth connection structure 1742 include the anisotropic conductive adhesive, and the third connection structure 1741 and the fourth connection structure 1742 are connected to each other.

The first protective structure 153B and the second protective structure 154B are located on the first repair region RR1 and the second repair region RR2 respectively. The first protective structure 153B is in contact with the repair light emitting diode 230A, the first bottom electrode 121, and the first top electrode 141, and covers the repair light emitting diode 230A, the first connection structure 1731 and the second connection structure 1732. The first protective structure 153B helps to fix the repair light emitting diode 230A, and may be used to protect the first connection structure 1731 and the second connection structure 1732. The second protective structure 154B covers the third connection structure 1741 and the fourth connection structure 1742. The second protective structure 154B may be used to protect the third connection structure 1741 and the fourth connection structure 1742.

Based on the above, in a manufacturing process of the display device in the disclosure, there is no need to modify the photomask used when forming the protective structure and/or the photomask used when forming the connection structure in response to the position of the faulty light emitting diode. Therefore, it is possible to significantly reduce the costs of the repair process.

What is claimed is:

1. A display device, comprising:
a circuit substrate comprising a first bottom electrode located in a first pixel region and a second bottom electrode located in a second pixel region, wherein the first pixel region comprises a first placement region and a first repair region, and the second pixel region comprises a second placement region and a second repair region;
a first light emitting diode and a second light emitting diode respectively located on the first pixel region and the second pixel region;
a first insulation structure and a second insulation structure respectively located on the first placement region and the second placement region and in contact with the first light emitting diode and the second light emitting diode respectively;
a first top electrode and a second top electrode respectively located on the first insulation structure and the second insulation structure, wherein the second light emitting diode is sandwiched between the second bottom electrode and the second top electrode;
a repair light emitting diode located on the first repair region and electrically connected to the first bottom electrode; and
a first protective structure and a second protective structure respectively located on the first repair region and the second repair region, wherein the first protective structure is in contact with the repair light emitting diode.

2. The display device according to claim 1, wherein the repair light emitting diode is a vertical light emitting diode, the first bottom electrode extends from the first placement region to the first repair region, and the second bottom electrode extends from the second placement region to the second repair region, wherein the display device further comprises:
a first connection structure filled in a first through hole of the first protective structure and connected to the repair light emitting diode, wherein a contact area between the first connection structure and the repair light emitting diode does not overlap the first bottom electrode in a vertical direction; and
a second connection structure filled in a second through hole of the second protective structure, wherein the second connection structure is separated from the second bottom electrode.

3. The display device according to claim 1, wherein a portion of the first protective structure extends from a side wall of the repair light emitting diode between a bottom surface of the repair light emitting diode and the circuit substrate.

4. The display device according to claim 1, further comprising:
a first support structure and a second support structure respectively located on the first repair region and the second repair region, wherein the first support structure is located between the repair light emitting diode and the circuit substrate.

5. The display device according to claim 1, wherein the repair light emitting diode is a horizontal light emitting diode, and the display device further comprises:
a first connection structure and a second connection structure respectively filled in a first through hole and a second through hole of the first protective structure, wherein the first connection structure connects the repair light emitting diode to the first bottom electrode, and the second connection structure connects the repair light emitting diode to the first top electrode; and
a third connection structure and a fourth connection structure respectively filled in a third through hole and a fourth through hole of the second protective structure, wherein the third connection structure is connected to the second bottom electrode, and the fourth connection structure is connected to the second top electrode.

6. The display device according to claim 1, wherein the repair light emitting diode is a horizontal light emitting diode, and the display device further comprises:
a first connection structure and a second connection structure respectively located on the first bottom electrode and the first top electrode, and connecting the repair light emitting diode to the first bottom electrode and the first top electrode respectively, wherein the first protective structure covers the first connection structure and the second connection structure.

7. The display device according to claim 6, further comprising:
a third connection structure and a fourth connection structure are respectively located on the second bottom electrode and the second top electrode, wherein the second protective structure covers the third connection structure and the fourth connection structure.

8. The display device according to claim 1, wherein the first insulation structure and the second insulation structure surround the first light emitting diode and the second light emitting diode respectively, and the first protective structure surrounds the repair light emitting diode.

9. The display device according to claim 1, further comprising:
a covering structure covering the first pixel region and the second pixel region and in contact with the first protective structure and the second protective structure.

10. The display device according to claim 9, wherein the covering structure comprises a color conversion layer.

11. The display device according to claim 1, wherein a portion of the repair light emitting diode overlaps the first bottom electrode in a vertical direction, and another portion of the repair light emitting diode does not overlap the first bottom electrode in the vertical direction.

12. The display device according to claim 1, wherein a horizontal distance between the first protective structure and the first insulation structure is substantially equal to a horizontal distance between the second protective structure and the second insulation structure.

13. A fabrication method of a display device, comprising:
providing a circuit substrate, wherein the circuit substrate comprises a first bottom electrode located in a first pixel region and a second bottom electrode located in a second pixel region, wherein the first pixel region comprises a first placement region and a first repair region, and the second pixel region comprises a second placement region and a second repair region;
placing a first light emitting diode and a second light emitting diode on the first pixel region and the second pixel region respectively;
forming a first insulation structure and a second insulation structure, wherein the first insulation structure and the second insulation structure are respectively located on the first placement region and the second placement region, and are in contact with the first light emitting diode and the second light emitting diode respectively;
forming a first top electrode and a second top electrode, wherein the first top electrode and the second top electrode are respectively located on the first insulation structure and the second insulation structure, and the second light emitting diode is sandwiched between the second bottom electrode and the second top electrode;
performing a test process, wherein the second light emitting diode emits light during the test process, and the first light emitting diode is faulty during the test process;
providing a repair light emitting diode on the first repair region; and
forming a first protective structure and a second protective structure, wherein the first protective structure and the second protective structure are respectively located on the first repair region and the second repair region, and the first protective structure is in contact with the repair light emitting diode.

14. The fabrication method according to claim 13, further comprising:
forming a first connection structure in a first through hole of the first protective structure to be connected to the repair light emitting diode, wherein a contact area between the first connection structure and the repair light emitting diode does not overlap the first bottom electrode in a vertical direction; and
forming a second connection structure in a second through hole of the second protective structure, wherein the second connection structure is separated from the second bottom electrode.
